(19) United States
(12) Patent Application Publication
(10) Pub. No.: US 2013/0141877 A1
(43) Pub. Date: Jun. 6, 2013

(54) FAN-OUT CIRCUIT AND ELECTRONIC DEVICE HAVING THE SAME

(71) Applicants: Chee-Wai Lau, Hsinchu County (TW); Tsao-Wen Lu, New Taipei City (TW); Chien-Ju Lin, New Taipei City (TW); Chien-Hao Fu, New Taipei City (TW); Tsang-Hong Wang, Chiayi City (TW)

(72) Inventors: Chee-Wai Lau, Hsinchu County (TW); Tsao-Wen Lu, New Taipei City (TW); Chien-Ju Lin, New Taipei City (TW); Chien-Hao Fu, New Taipei City (TW); Tsang-Hong Wang, Chiayi City (TW)

(73) Assignee: AU OPTRONICS CORPORATION, Hsinchu (TW)

(21) Appl. No.: 13/444,859

(22) Filed: Apr. 12, 2012

(30) Foreign Application Priority Data
Dec. 2, 2011 (TW) 100144405

(51) Int. Cl. H05K 7/00

(52) U.S. Cl. 361/748

(57) ABSTRACT

A fan-out circuit electrically connected to a driver and a plurality of signal lines is provided. The fan-out circuit includes a first fan-out trace including a first and a second conductive line, and a second fan-out trace including a third and a fourth conductive line. The second conductive line is connected between the first conductive line and one of the signal lines. The length of the second and fourth conductive lines are L1′ and L2′ respectively. An obtuse included angle is formed between the first and second conductive lines. The width of the first and third conductive lines is W1. The fourth conductive line is electrically connected to the third conductive line and another one of the signal lines. The obtuse included angle is formed between the third and fourth conductive lines. The width of the second and fourth conductive lines is W2, and (W2/L1′)>(W2/L2′) and L1′<L2′.

### CROSS-REFERENCE TO RELATED APPLICATION

This application claims the priority benefit of Taiwan application serial no. 100144405 filed on Dec. 12, 2011. The entirety of the above-mentioned patent application is hereby incorporated by reference herein and made a part of this specification.

### BACKGROUND OF THE DISCLOSURE

1. Field of the Disclosure

The document relates to an electronic apparatus, and more particularly to a fan-out circuit.

2. Description of Related Art

As technology advances, bulky cathode ray tube (CRT) displays have gradually passed into history. Therefore, planar displays such as the liquid crystal display (LCD), the organic electro-luminescent display, the field emission display (FED), and the plasma display panel (PDP) are becoming mainstream.

A typical planar display has an active area and a peripheral circuit area, in which a plurality of pixels and signal lines are disposed in the active area, and a fan-out circuit is designed on the peripheral circuit area. The signal lines extend from the active area to the peripheral circuit area, and electrically connect to the driver IC via the fan-out circuit.

The fan-out circuit has a plurality of fan-out traces. As the relative position of the driver IC and the corresponding signal lines varies, a noticeable resistance difference exists between the fan-out traces. Accordingly, how to decrease the resistance difference between each fan-out trace is an issue that requires urgent attention.

### SUMMARY OF THE DISCLOSURE

The disclosure provides a fan-out circuit and an electronic apparatus having the fan-out circuit.

In one aspect, the disclosure provides a fan-out circuit electrically connected between a driver and a plurality of signal lines. The fan-out circuit includes a first fan-out trace and a second fan-out trace. The first fan-out trace includes a first conductive line and a second conductive line. The first conductive is parallel with the signal lines and electrically connected to the driver. The second conductive line is connected between the first conductive line and one of the signal lines. An obtuse included angle (θ+(π/2)) is formed between the first conductive line and the second conductive line, and θ<90°. The second fan-out trace includes a third conductive line and a fourth conductive line. The third conductive line is parallel with the signal lines and electrically connected to the driver. The fourth conductive line is connected between the third conductive line and another one of the signal lines. A length difference between the first conductive line and the third conductive line is L1, a width of the first conductive line and the third conductive line is W1, an obtuse included angle (θ+(π/2)) is formed between the third conductive line and the fourth conductive line, a length difference between the second conductive line and the fourth conductive line is L2, a width of the second conductive line and the fourth conductive line is W2, and L1, L2, W1, and W2 satisfy the following equations:

(L1/W1)=(L2/W2); and

W1<W2.

In another aspect, the disclosure provides another fan-out circuit electrically connected between a driver and a plurality of signal lines. The fan-out circuit includes a first fan-out trace and a second fan-out trace. The first fan-out trace includes a first conductive line and a second conductive line. The first conductive line is parallel with the signal lines and electrically connected to the driver. The second conductive line is connected between the first conductive line and one of the signal lines, in which a length of the second conductive line is L1′, and an obtuse included angle (θ+(π/2)) is formed between the first conductive line and the second conductive line. The second fan-out trace includes a third conductive line and a fourth conductive line. The third conductive line is parallel with the signal lines and electrically connected to the driver. A width of the first conductive line and the third conductive line is W1. The fourth conductive line is connected between the third conductive line and another one of the signal lines, and a length of the fourth conductive line is L2′. An obtuse included angle (θ+(π/2)) is formed between the third conductive line and the fourth conductive line, in which a width of the second conductive line and the fourth conductive line is W2, and L1′, L2′, W1, and W2 satisfy the equation:

(W2/L1′)>(W2/L2′), and L1′<L2′.

According to an embodiment of the disclosure, the fan-out circuit may further include at least a third fan-out trace, in which an extended direction of the third fan-out trace is parallel with the signal lines, a length of the third fan-out trace is L0, and a width of the third fan-out trace is W1.

According to an embodiment of the disclosure, W1, W2, and θ satisfy the equation:

W2·(sin θ)=W1.

According to an embodiment of the disclosure, a line space between the second conductive line and the fourth conductive line neighboring each other is S, a pitch between the second conductive line and the fourth conductive line neighboring each other is P, and S, P, W1, and W2 satisfy the equation:

$$W 2 = \frac{- S + \sqrt{( {S}^{2} + ( 4 W 1 \cdot P ) )}}{2} .$$

According to an embodiment of the disclosure, a first connection node is between the first conductive line and the second conductive line, a second connection node is between the third conductive line and the fourth conductive line, and the first connection node and the second connection node are located at different horizontal levels perpendicular to the first conductive line.

According to an embodiment of the disclosure, a length of the first conductive line is substantially longer than a length of the third conductive line.

The disclosure provides an electronic apparatus including a substrate and the afore-described fan-out circuit, and the fan-out circuit is disposed on the substrate.

In the fan-out circuits according to embodiments of the disclosure, the resistance of each fan-out trace is close to each other. Therefore, when signals are being transmitted in different fan-out traces, the various levels of signal decay from the transmitted signals due to the large resistance difference of each fan-out trace can be mitigated.

To make the above and other features and advantages of the application more comprehensible, several embodiments accompanied with figures are detailed as follows.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic view illustrating a fan-out circuit according to a first exemplary embodiment.

FIG. 2 is a schematic view illustrating a fan-out circuit according to a second exemplary embodiment.

### DESCRIPTION OF EMBODIMENTS

### First Exemplary Embodiment

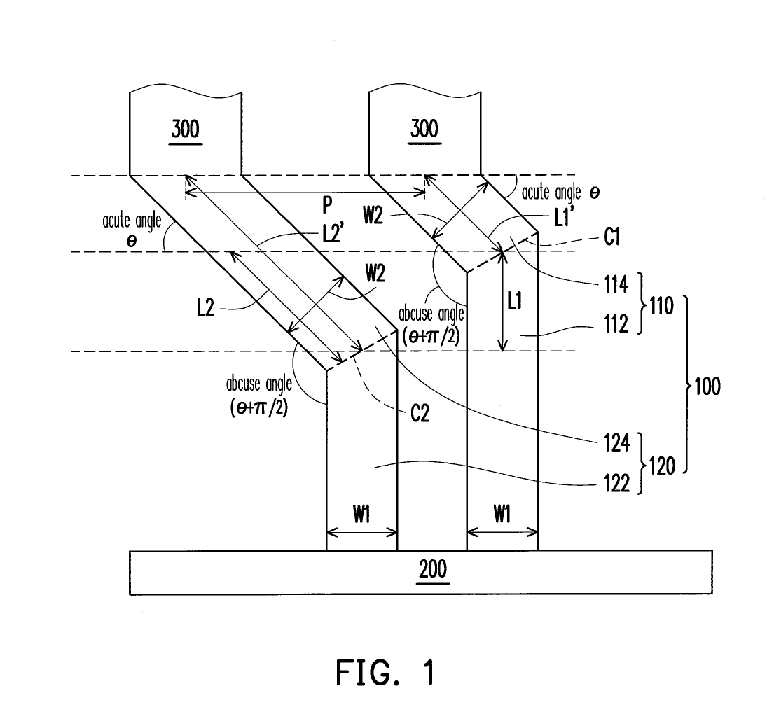

FIG. 1 is a schematic view illustrating a fan-out circuit according to a first exemplary embodiment. Referring to FIG. 1, a fan-out circuit 100 of the present embodiment is electrically connected between a driver 200 and a plurality of signal lines 300. The fan-out circuit 100 includes a first fan-out trace 110 and a second fan-out trace 120. In the present embodiment, each of the first fan-out trace 110 and the second fan-out trace 120 has a single layer structure or a multi-layer structure. Moreover, a material of the fan-out traces 110 and 120 includes a metal, an alloy, a metal oxide, an alloy oxide, a metal nitride, an alloy nitride, a metal oxynitride, an alloy oxynitride, or other appropriate materials.

The first fan-out trace 110 includes a first conductive line 112 and a second conductive line 114. The first conductive line 112 is substantially parallel with the signal lines 300 and electrically connected to the driver 200. In other words, an extended direction of the first conductive line 112 is substantially the same as an extended direction of the signal lines 300. The second conductive line 114 is connected between the first conductive line 112 and one of the signal lines 300. That is, the second conductive line 114 is connected to the corresponding signal line 300, and the second conductive line 114 is located between the corresponding signal line 300 and the first conductive line 112. Moreover, an obtuse included angle (θ+(π/2)) is formed between the first conductive line 112 and the second conductive line 114, and θ< about 90°. In the disclosure, (π/2) means about 90° mathematically. The second fan-out trace 120 includes a third conductive line 122 and a fourth conductive line 124. The third conductive line 122 is substantially parallel with the signal lines 300 and electrically connected to the driver 200. In other words, an extended direction of the third conductive line 122 is substantially the same as an extended direction of the signal lines 300. The fourth conductive line 124 is connected between the third conductive line 122 and another one of the signal lines 300. In other words, the fourth conductive line 124 is connected to the corresponding signal line 300, and the fourth conductive line 124 is located between the corresponding signal line 300 and the third conductive line 122. Moreover, assuming a length difference between the first conductive line 112 and the third conductive line 122 is L1, a width of the first conductive line 112 and the third conductive line 122 is W1, an obtuse included angle (θ+(π/2)) is formed between the third conductive line 122 and the fourth conductive line 124, a length difference between the second conductive line 114 and the fourth conductive line 124 is L2, a width of the second conductive line 114 and the fourth conductive line 124 is W2, then L1, L2, W1, and W2 satisfy the following equations (1) and (2):

(L1/W1)=(L2/W2) (1)

W1<W2 (2).

In the present embodiment, assuming a length of the second conductive line 114 of the first fan-out trace 110 is L1′, a length of the fourth conductive line 124 of the second fan-out trace 120 is L2′, then L1′, L2′, W1, and W2 satisfy the following equations (3) and (4):

(W2/L1′)>(W2/L2′) (3)

L1′<L2′ (4).

From equations (1) and (3), it can be derived that L2=L2′−L1′.
In the present embodiment, W1, W2, and θ satisfy the following equation (5):

(W2/L1′)>(W2/L2′) (5).

Equation (5) is derived as below:

(L1/W1)=(L2/W2)

((L1/L2)/W1)=(1/W2)

((sin θ)/W1)=(1/W2)

W2·(sin θ)=W1, in which “·” is a multiplication symbol.

It should be noted that, the obtuse angle (θ+(π/2)) is related to the width of the driver 200, a pitch of the signal contacts on the driver 200, and a pitch of the signal lines 300. Typically, the obtuse angle (θ+(π/2)) is approximately 135 degrees, although the invention is not limited thereto. In other embodiments, the obtuse angle may be any angle greater than 90 degrees and less than 180 degrees, for example, 95 degrees, 105 degrees, 115 degrees, 125 degrees, 145 degrees, 155 degrees, 165 degrees, 175 degrees, or other suitable degrees.

In the present embodiment, a line space between the second conductive line 114 and the fourth conductive line 124 neighboring each other is S, a pitch between the second conductive line 114 and the fourth conductive line 124 neighboring each other is P, and S, P, W1, and W2 satisfy the following equation (6):

$$W 2 = \frac{- S + \sqrt{( {S}^{2} + ( 4 W 1 \cdot P ) )}}{2} . \qquad ( 6 )$$

Equation (6) is derived as below:

$$W 2 \cdot ( sin θ ) = W 1$$

$$W 2 \cdot ( ( W 2 + S ) / P ) = W 1$$

$$W {2}^{2} + ( W 2 \cdot S ) - ( W 1 \cdot P ) = 0$$

$$W 2 = \frac{- S + \sqrt{( {S}^{2} + ( 4 W 1 \cdot P ) )}}{2}$$

In the present embodiment, a first connection node C1 is between the first conductive line 112 and the second conductive line 114, a second connection node C2 is between the third conductive line 122 and the fourth conductive line 124, and the first connection node C1 and the second connection node C2 are located at different horizontal levels (the horizontal dotted lines in FIG. 1) perpendicular to the first conductive line 112. In other words, a connecting line between the first connection node C1 and the second connection node C2 has a slope of greater than about 0.

The fan-out circuit 100 depicted in FIG. 1 may be applied in an electronic apparatus. That is, the electronic apparatus includes a substrate and the afore-described fan-out circuit 100, and the fan-out circuit 100 is disposed on the substrate. For example, the substrate is a circuit board or a display panel. In the present embodiment, the circuit board is a flexible circuit board or a rigid circuit board. The display panel is an organic electro-luminescent display panel, a plasma display panel, a field emission display panel, an electrophoresis display panel, an electro-wetting display panel, or a liquid crystal panel, for example.

In the fan-out circuit of the present embodiment, the resistance of each fan-out trace is close to each other. Therefore, when signals are being transmitted in different fan-out traces, the various levels of signal decay from the transmitted signals due to the large resistance difference of each fan-out trace can be mitigated.

### Second Exemplary Embodiment

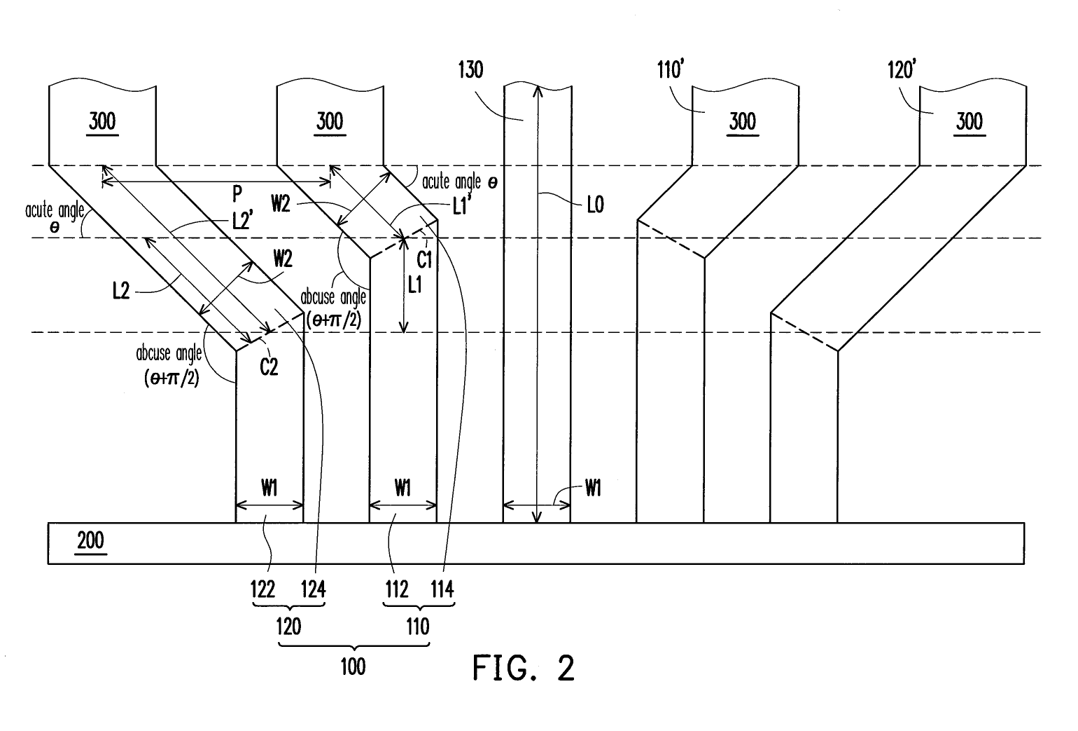

FIG. 2 is a schematic view illustrating a fan-out circuit according to a second exemplary embodiment. Referring to FIGS. 1 and 2, a fan-out circuit 100′ of the present embodiment is similar to the fan-out circuit 100 of the first embodiment. A difference between the two fan-out circuits is that the fan-out circuit 100′ of the present embodiment further includes at least at least a third fan-out trace 130, in which an extended direction of the third fan-out trace 130 is substantially parallel with the signal lines 300. In other words, the extended direction of the third fan-out trace 130 is the same as the extended direction of the signal lines 300. A length of the third fan-out trace 130 is L0, and a width of the third fan-out trace 130 is W1. In the present embodiment, the third fan-out trace 130 has a single layer structure or a multi-layer structure. Moreover, a material of the third fan-out traces 130 includes a metal, an alloy, a metal oxide, an alloy oxide, a metal nitride, an alloy nitride, a metal oxynitride, an alloy oxynitride, or other appropriate materials.

In addition, the fan-out circuit 100′ of the present embodiment includes a plurality of first fan-out traces 110 and 110′ and a plurality of second fan-out traces 120 and 120′. The first fan-out trace 110 and the second fan-out trace 120 are located on a side (e.g. left side) of the third fan-out trace 130. The first fan-out trace 110′ and the second fan-out trace 120′ are located on another side (e.g. right side) of the third fan-out trace 130. Moreover, the design principles of the first fan-out trace 110′, the second fan-out trace 120′ are the same as the design principles for the first fan-out trace 110 and the second fan-out trace 120.

In the present embodiment, the first fan-out trace 110 and the second fan-out trace 120 located on a side of the third fan-out trace 130 is substantial symmetrically distributed, for example, with the first fan-out trace 110′ and the second fan-out trace 120′ located on another side of the third fan-out trace 130. It should be noted that, the invention is not limited to substantial symmetrically distributing the first fan-out trace 110, the second fan-out trace 120, the first fan-out trace 110′, the second fan-out trace 120′ located on two sides of the third fan-out trace 130. Persons skilled in the art may adjust the distribution mode based on a design requirement. For example, the first fan-out trace 110, the second fan-out trace 120, the first fan-out trace 110′, the second fan-out trace 120′ may be asymmetrically distributed on two sides of the third fan-out trace 130, or the first fan-out trace 110′, the second fan-out trace 120′, and the third fan-out trace 130 may be alternately arranged.

Similarly, the fan-out circuit 100′ depicted in FIG. 2 may be applied in an electronic apparatus. That is, the electronic apparatus includes a substrate and the afore-described fan-out circuit 100′, and the fan-out circuit 100′ is disposed on the substrate. For example, the substrate is a circuit board or a display panel. In the present embodiment, the circuit board is a flexible circuit board or a rigid circuit board. The display panel is an organic electro-luminescent display panel, a plasma display panel, a field emission display panel, an electrophoresis display panel, an electro-wetting display panel, or a liquid crystal panel, for example.

Although the invention has been disclosed by the above embodiments, they are not intended to limit the invention. Those skilled in the art may make some modifications and alterations without departing from the spirit and scope of the invention. Therefore, the protection range of the invention falls in the appended claims.

What is claimed is:

1. A fan-out circuit electrically connected between a driver and a plurality of signal lines, the fan-out circuit comprising:
a first fan-out trace comprising:
a first conductive line parallel with the signal lines and electrically connected to the driver; and
a second conductive line connected between the first conductive line and one of the signal lines, wherein an obtuse included angle (θ+(π/2)) is formed between the first conductive line and the second conductive line, and θ<90°;
a second fan-out trace comprising:
a third conductive line parallel with the signal lines and electrically connected to the driver, wherein a length difference between the first conductive line and the third conductive line is L1, and a width of the first conductive line and the third conductive line is W1; and
a fourth conductive line connected between the third conductive line and another one of the signal lines, an obtuse included angle (θ+(π/2)) being formed between the third conductive line and the fourth conductive line, wherein a length difference between the second conductive line and the fourth conductive line is L2, a width of the second conductive line and the fourth conductive line is W2, and L1, L2, W1, and W2 satisfy the equations:
(L1/W1)=(L2/W2); and
W1<W2.

2. The fan-out circuit of claim 1, further comprising at least a third fan-out trace, wherein an extended direction of the third fan-out trace is parallel with the signal lines, a length of the third fan-out trace is L0, and a width of the third fan-out trace is W1.

3. The fan-out circuit of claim 1, wherein W1, W2, and θ satisfy the equation:
W2·(sin θ)=W1.

4. The fan-out circuit of claim 1, wherein a line space between the second conductive line and the fourth conductive line neighboring each other is S, a pitch between the second conductive line and the fourth conductive line neighboring each other is P, and S, P, W1, and W2 satisfy the equation:
$$W 2 = \frac{- S + \sqrt{( {S}^{2} + ( 4 W 1 \cdot P ) )}}{2} .$$

5. The fan-out circuit of claim 1, wherein a first connection node is between the first conductive line and the second conductive line, a second connection node is between the third conductive line and the fourth conductive line, and the first connection node and the second connection node are located at different horizontal levels perpendicular to the first conductive line.

6. The fan-out circuit of claim 1, wherein a length of the first conductive line is substantially longer than a length of the third conductive line.

7. An electronic apparatus, comprising:
a substrate; and
a fan-out circuit of claim 1, the fan-out circuit being disposed on the substrate.

8. A fan-out circuit electrically connected between a driver and a plurality of signal lines, the fan-out circuit comprising:
a first fan-out trace comprising:
a first conductive line parallel with the signal lines and electrically connected to the driver; and
a second conductive line connected between the first conductive line and one of the signal lines, wherein a length of the second conductive line is L1′, and an obtuse included angle (θ+(π/2)) is formed between the first conductive line and the second conductive line;
a second fan-out trace comprising:
a third conductive line parallel with the signal lines and electrically connected to the driver, wherein a width of the first conductive line and the third conductive line is W1; and
a fourth conductive line connected between the third conductive line and another one of the signal lines, an obtuse included angle (θ+(π/2)) being formed between the third conductive line and the fourth conductive line, wherein a length of the fourth conductive line is L2′, a width of the second conductive line and the fourth conductive line is W2, and L1′, L2′, W1, and W2 satisfy the equation:
(W2/L1′)>(W2/L2′), and L1′<L2′.

9. The fan-out circuit of claim 8, wherein W1, W2, and θ satisfy the equation:
W2·(sin θ)=W1.

10. The fan-out circuit of claim 8, wherein a line space between the second conductive line and the fourth conductive line neighboring each other is S, a pitch between the second conductive line and the fourth conductive line neighboring each other is P, and S, P, W1, and W2 satisfy the equation:
$$W 2 = \frac{- S + \sqrt{( {S}^{2} + ( 4 W 1 \cdot P ) )}}{2} .$$

11. The fan-out circuit of claim 8, wherein a first connection node is between the first conductive line and the second conductive line, a second connection node is between the third conductive line and the fourth conductive line, and the first connection node and the second connection node are located at different horizontal levels perpendicular to the first conductive line.

12. The fan-out circuit of claim 11, wherein a connecting line between the first connection node and the second connection node has a slope of greater than 0.

13. An electronic apparatus, comprising:
a substrate; and
a fan-out circuit of claim 8, the fan-out circuit being disposed on the substrate.
